(19) United States
(12) Patent Application Publication
(10) Pub. No.: US 2004/0143963 A1
(43) Pub. Date: Jul. 29, 2004

(54) Assembly system and method for assembling components on substrates

(76) Inventors: Mohammad Mehdianpour, Munchen (DE); Ralf Schulz, Munchen (DE)

Correspondence Address: HARNESS, DICKEY & PIERCE, P.L.C., P.O.BOX 8910, RESTON, VA, 20195, US

(21) Appl. No.: 10/478,374

(22) PCT Filed: May 17, 2002
(86) PCT No.: PCT/DE02/01787

(30) Foreign Application Priority Data
May 23, 2001 (DE) 10125392.3
May 23, 2001 (DE) 10125391.5

(51) Int. Cl. H05K 3/30; B23P 19/00

(52) U.S. Cl. 29/832; 29/742

(57) ABSTRACT

The invention relates to an assembly system and method for assembling components on substrates, with, for example, two substrate support pairs arranged perpendicular to a conveyor run, comprising substrate supports (110, 130, 120, 140) which may be displaced perpendicular to the conveyor run. Assembly fields (500, 550) are arranged to the side of the conveyor run, which can be supplied with circuit boards (L) by means of the substrate supports (110, 130, 120, 140). A loading device (210) and an unloading device (220) are arranged along the conveyor run (T), by means of which the circuit boards (L) can be placed on the substrate supports (110, 130, 120, 140). The loading device (210) and the unloading device (22) may be displaced along the conveyor run in a loading direction and an unloading direction. A flexible execution of assembly processes is possible with the above arrangement. Furthermore, non-productive time, such as for example the time required to exchange an assembled circuit board (L) for an unassembled circuit board (L) in the assembly field is eliminated.

The invention relates to an assembly system and a method for assembling components on substrates, with the substrates able to be fed via a basically linear conveyor run and with at least one feed device for feeding components as well as at least one assembly field with a handling device for assembling the fed components on the substrate being located on the two sides of the conveyor run.

There is currently widespread use of assembly systems for assembling components, especially SMD components, on substrates. Conventionally the substrates are fed in on a conveyor run. The assembly fields are arranged along the conveyor run. If a substrate reaches an assembly field its position is determined relative to a handling device which is located in the assembly field for assembling the components on the substrates. Components are then assembled on the substrate by means of the handling device.

If a fault occurs in an assembly field of a conventional assembly system which slows down assembly in the assembly field or brings it to a standstill, the entire conveyor run will be slowed down or halted. This has a decidedly adverse effect on the performance of conventional assembly systems.

The object of the invention is to specify an assembly system and a method for assembling components on substrates in which the assembly performance is improved and which is fault tolerant.

The object is achieved by an assembly system with the features according to claim 1 as well as a method for assembling components on substrates with the features according to claim 17. Preferred embodiments of the invention are claimed in the dependent claims.

The assembly system according to claim 1 makes it possible to provide an assembly field on both sides of a conveyor run, in which components can be assembled on a substrate. The substrates are moved by means of pairs of supports between the conveyor run and the assembly field. A pair of substrate supports features two substrate supports. Each of the two substrate supports is assigned to an assembly field on one side of the conveyor run. The substrate supports of a pair of substrate supports have a common direction of movement along which the assembly fields are arranged at regular intervals. The direction of movement is at an angle to the direction of transport of the conveyor run, in particular it is at right angles to it.

With the assembly system in accordance with the invention it is possible to move substrates fed along a conveyor run sideways to assembly fields which are located on both sides of the conveyor run. For example a substrate is transported with a substrate support of a pair of substrate supports from the conveyor run to an assembly field. While the substrate is being assembled it is possible with the assembly system in accordance with the invention to feed substrates with the other substrate support of the pair of substrate supports along the conveyor run past the assembly field at which a substrate is being assembled. It is also possible, by means of the other substrate support of the pair of substrate supports, to direct a further substrate to the other assembly field on the other side of the conveyor run. In accordance with the invention this ensures that even with a fault within an assembly field, which with conventional equipment would bring the conveyor run to a halt, in accordance with the invention, substrates can continue to be transported along the conveyor run. This increases the performance and the operational safety of the assembly system in accordance with the invention.

The areas of movement of the substrate supports of each pair of substrate supports can overlap in the area of the conveyor run. This makes it possible for substrates to be able to be transferred directly from the conveyor run to the substrate support with an additional transfer device. An even higher throughput speed is achieved.

It is also possible to arrange two pairs of substrate supports, a first pair of substrate supports and a second pair of substrate supports, one after another in the direction of transport. This makes it possible to assign two substrate supports to an assembly field in each case. This serves to reduce non-productive time, since a single assembly field can be supplied with substrates by means of two substrate supports. While one substrate is being assembled, the other substrate can be changed.

It is further possible to provide a loading device. The loading device features a rest position which lies in the direction of transport before the pairs of substrate supports. By means of the loading device substrates fed along the conveyor run can be moved in the direction of transport or along the conveyor run to the pairs of substrate supports. In particular this facilitates the feeding of substrates to the second pair of substrate supports in the direction of transport of the substrates. If the substrate supports of the first pair of substrate supports are moved to the relevant assembly fields a space would otherwise arise between the conveyor run and area of movement of the second pair of substrate supports. However this can be bridged by means of the loading device. To this end a substrate is transferred from the conveyor run to the loading device. The loading device will be moved in the direction of transport to the second pair of substrate supports and can transfer the substrate to a substrate support of the second substrate support pair, from which it can be moved to the other assembly field. This makes it possible for the assembly system to be more flexible.

In addition the loading device makes it possible to forward substrates to a subsequent assembly system in which component assembly is taking place at all the assembly fields of the one assembly system. To this end the substrate transferred by means of the loading device is moved across all movement areas of the pairs of substrate supports and passed on to the conveyor run of a subsequent assembly system in the direction of transport.

In a similar way an unloading system can also be provided which can be moved along the conveyor run and for which the rest position lies in the direction of transport after the pairs of substrate supports. It is also possible to use the unloading device to move substrates from the conveyor run out over the areas of movement of the pairs of substrate supports to the conveyor of a subsequent assembly system in the direction of transport. It is also possible with the unloading device to take a substrate from a substrate support of a pair of substrate supports and for example transfer it to the conveyor run of a subsequent assembly system in the direction of transport.

The loading device or the unloading device are for example supported above the conveyor run. The result is that the loading device or the unloading device and the substrate supports along the conveyor run can use the same area of movement since the substrate supports are in particular supported below the conveyor run at the same height as the conveyor run.

The substrate supports can be provided with reference points and a measurement system for determining the position of the substrates relative to the reference points can be provided. To enable the positions of all substrates on the relevant substrate supports to be determined with a number of pairs of substrate supports arranged one after the other, the measurement system can be moved along the conveyor run over the substrate supports. This makes it possible to determine the positions of substrates on all substrate supports of the assembly system with only a single measurement system. Measurements can for example be undertaken while a substrate support is being moved away from the conveyor run to the assembly field. Cameras in particular come into consideration as measurement systems. The positions of the substrates on the substrate supports are determined by means of an evaluation unit which is linked to the cameras. In accordance with a development of the invention a transport device is located along the conveyor run which for example features transport bands or transport belts. The transport device allows the substrates to be transported in the direction of transport to the loading device or to the substrate supports and/or away from the unloading device or from the substrate supports. The conveyor run can also be designed on the substrate supports or on the loading device and/or unloading device for positioning the substrates on the latter.

A further, even more powerful embodiment of the invention provides for a second conveyor run which runs in parallel to the conveyor run and is located directly beside the conveyor run. Similarly to the above-mentioned embodiment of the invention there is also provision for a second loading device and second unloading device along the second conveyor run. This makes it possible to feed substrates simultaneously along the two conveyor runs. These will be fed via the loading device or the second loading device to the substrate supports. It is possible using the two loading devices to feed substrates to the substrate support on both sides of the conveyor run and second conveyor run. To this end the areas of movement of the substrate support pairs overlap with the areas of movement of the loading devices or the unloading devices. Flexible distribution of the substrates to the appropriate free or empty substrate supports is possible.

In accordance with a further embodiment of the invention the substrates can be moved from a first assembly field by means of the substrate supports and/or by means of the substrate supports and loading devices and/or the substrate supports and unloading devices via the conveyor run to a second assembly field. This involves using a substrate support to move a substrate positioned on a substrate support from a first assembly field into the area of the conveyor run. From here it can for example be transferred to a further adjacent substrate support which moves it to a second assembly field.

Depending on the arrangement of the pairs of substrate supports along the conveyor run and in accordance with the number of the pairs of substrate supports this makes it possible for example to transfer substrates diagonally across the conveyor run from an assembly field to another assembly field.

The substrates can however essentially also be transferred at right angles to the conveyor run from one assembly field to another assembly field. This makes it possible during assembly for example to assemble a greater number of different components to be assembled on a substrate with a single assembly system. The substrate to be assembled in this way is transferred in this case from one assembly field to one or more following assembly fields. Since there is provision at each assembly field for a plurality of feed devices, at which components to be assembled are provided in each case, it is possible to have available a very large number of different components for assembly on the substrates at a single assembly system.

It is possible to combine a number of assembly systems into an assembly plant. In this case the assembly systems can be positioned in such a way that the area of movement of the loading device of subsequent assembly systems in the direction of transport borders directly on the area of movement of the substrate supports of the preceding assembly systems located in the direction of transport. In this case the area of movement of the loading device which is located between assembly systems can overlap with the areas of movement of the substrate supports of the two assembly systems. This allows an even more flexible distribution of the substrates to the individual substrate supports. Depending on whether a large number of different components are to be assembled on the substrates with the assembly system or whether a large number of substrates are to be assembled simultaneously in parallel with a relatively small assortment of components the substrates are assembled on a single assembly field of the assembly plant or on a number of assembly fields in turn.

Another embodiment of the assembly plant provides for a number of assembly systems to be arranged in such a way that the area of movement of the loading devices of the downstream assembly systems located in the direction of transport is directly adjacent to the area of movement of the unloading devices of the assembly systems located in the upstream direction of the direction of transport.

Similarly to the previously mentioned assembly system there is still also an unloading device located between the pairs of substrate supports of the individual assembly systems. This means that there is always a loading device and an unloading device arranged one after the other between the individual assembly systems. Both the loading device and also the unloading device are designed to be movable in the direction of transport. Thus, with this embodiment of the invention, two mobile buffers are available in each case between the individual assembly systems in the direction of transport.

A method for assembling components on substrates is also created by the invention. The components are fed on an essentially linear conveyor run. On both sides of the conveyor run there is at least one feed device to feed the components and at least one assembly field with a handling device for assembling the fed components on the substrate. The substrates will be moved by means of at least of one pairs of substrate supports which features two substrate supports, from the conveyor run into an area of movement in one direction of movement of the substrate supports, with the area of movement of the substrate supports overlapping with the conveyor run. At the assembly fields components are assembled onto the substrates by the handling devices.

By moving the substrates using a pair of substrate supports which only moves in one direction, along which the substrate supports can be moved in their area of movement, it is possible at one point in the conveyor run by means of two substrate supports to transport substrates both to an assembly field on one side of the conveyor run and also to an assembly field on the other side of the conveyor run. This facility can for example take account of different speeds of assembly processing in the individual assembly fields and can optimize distribution of the substrates to the assembly fields.

The substrates can also be moved, by means of a loading device which can be moved along the conveyor run and for which the rest position lies in the direction of transport before the substrate supports, from an acceptance position at the rest position of the loading device to a transfer position. The acceptance position lies especially before the rest position of the loading device and the transfer position lies in the direction of transport after the substrate supports. This makes it possible at the assembly field, if the system is fully loaded or if faults have occurred, to pass on substrates in the direction of transport, which avoids a shutdown of an assembly plant consisting of one or more assembly systems.

An unloading device can still be used to pass on the substrates. The unloading device is provided for removing substrates from the substrate supports and can be moved along the conveyor run. The rest position of the unloading device lies in the direction of transport after the substrate supports. For passing the substrates on the loading device and the unloading device are moved directly from the acceptance position or the transfer position into an intermediate position in each case. The unloading device is moved directly from the intermediate position into the transfer position. In this case the intermediate position is located in the direction of transport in the area of the substrate supports.

A substrate picked up by the loading device at the acceptance position is taken by the loading device to the intermediate position and there it can be moved by the unloading device into the transfer position. In particular the loading device and the unloading device can in this case each be moved towards each other by half the space between the loading device and unloading device to enable the substrate to be transferred from the loading device to the unloading device. This allows an even faster passing on of a substrate across the substrate support area.

In accordance with a further embodiment of the invention it is possible to use a measurement system to determine the rest position of the substrates relative to reference points on the substrate supports while the substrates are being moved from the substrate supports to the assembly field. The measurement system is in this case located above the conveyor run and can be moved along the conveyor run. This allows the measurement system to be moved along the conveyor run over the direction of movement of the corresponding substrate support in order to determine the position of a substrate on a substrate support. After the transfer of the substrate to the substrate support the substrate support is moved at an angle to the conveyor run to the corresponding assembly field. During this movement the substrate and the reference points on the substrate support pass through the recording field of the measurement system. This makes it possible for the position of the substrates to be rapidly determined relative to the reference points on the substrate supports.

The invention will now be explained in more detail using preferred exemplary embodiments which refer to the drawing in the document. The drawing shows:

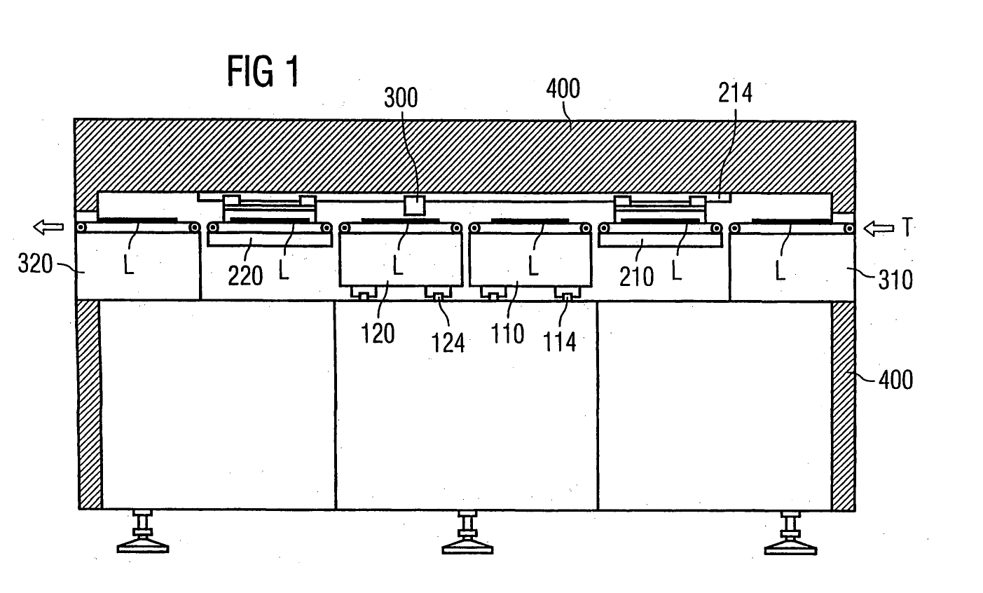

FIG. 1 a schematic side view of a preferred embodiment of the invention and

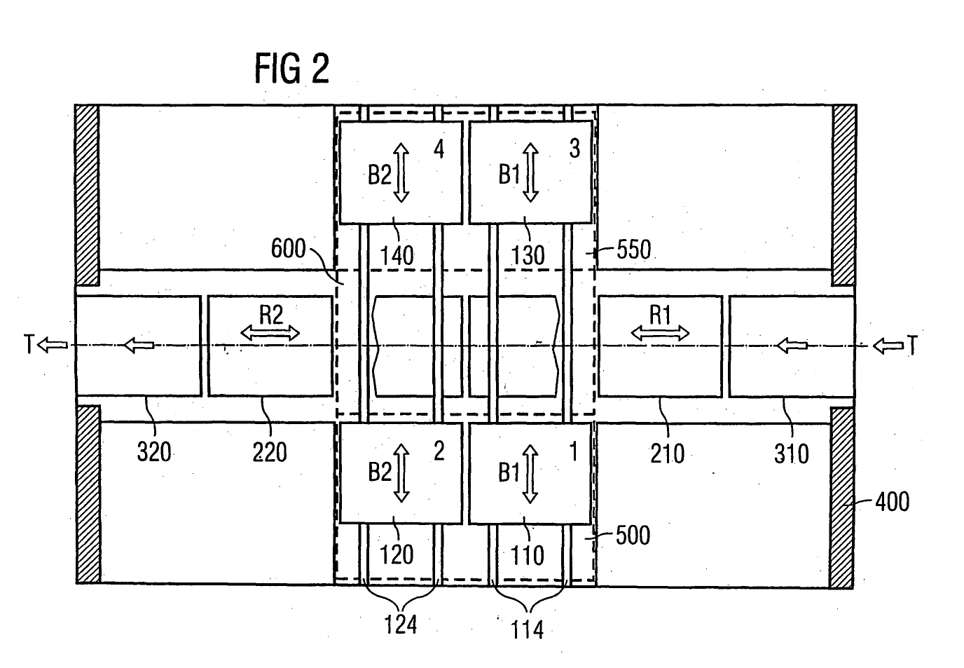

FIG. 2 a schematic section of the preferred embodiment viewed from above.

FIGS. 1 and 2 show a preferred embodiment of the assembly system in accordance with the invention. In this case a chassis 400 has basically rectangular footprint. Along the length of chassis 400 there is a conveyor run running in direction of transport T. Along the conveyor run substrates, preferably printed circuit boards, are fed to the assembly system or removed from this system. The printed circuit boards L are preferably fed in at in input station 310 which features an acceptance position.

To enable circuit boards L to be transported, the input station 310 is for example provided with transport belts. Following on from the input station 310 in the direction of transport T there is a loading device 210. From the input station 310 circuit boards L can be transferred to loading device 210. The loading device 210 can for example feature transport belts for transporting the circuit boards L.

The loading device 210 is supported on a bar-shaped guide device 214 which is designed to be above the conveyor run on chassis 400 and to extend along the conveyor run. A measurement system 300, especially a camera, is located on the guide device 214 and can be moved along the conveyor run. The loading device 210 can be moved, as can be seen from FIG. 2, along the conveyor run. For example the loading device can be moved from its rest position visible in FIGS. 1 and 2 within a central overlapping area 600.

Perpendicular to the direction of transport T two guide devices 114 or 124 are located in the direction of transport after the rest position of the loading device 210. Each guide device is equipped with a substrate support pair, 110, 130 or 120, 140 respectively. Each pair of substrate supports features two substrate supports 110 and 130 or 120 and 140 respectively. The substrate supports 110, 130, 120, 140 can be moved on the guide device 114 or 124 at an angle to the direction of transport T. Each substrate support can in this case be moved within the central overlapping area 600 as well as in a first assembly field 500 and a second assembly field 550.

Following on in the direction of transport from guide devices 114 and 124 there is provision for an unloading device 220 which features a transfer position. The unloading device 220 is constructed in a similar way to the loading device 210 and is also located on the guide device 214. The unloading device can also be moved from its rest position into the entire central overlapping area 600 along the conveyor run. Located after the unloading device 220 is an output station 320. The output station 320 is constructed in a similar way to the input station 310.

Both the substrate supports and the loading device 210 and the unloading device 220 of the assembly system in accordance with the invention can be provided with transport belts (not shown) to enable circuit boards L to be moved on them. The first assembly field 500 and the second assembly field 550 are each positioned to one side of the conveyor run. The substrate supports as well as the unloading device 220 and the loading device 210 can for example be guided by means of guide elements along their respective guide device 124 or 114. The guide elements are especially linear bearings.

The sequence of assembly operations which are carried out with this equipment is explained in greater detail below.

Along the conveyor run for example a circuit board L is made available to an input station 310. The loading device 210 is moved in a direction of loading R1 along the conveyor run until loading device 210 reaches its rest position. In this state the circuit board L can be transferred from the input station 310 to the loading device 210, by transporting the circuit board using transport belts for example for which there is provision on the loading device 210 and the input station 310.

The circuit board L can subsequently be moved to one of four circuit board positions 1, 2, 3 or. 4. To move the circuit board to one of positions 1 or 3 the loading device 210 remains in its rest position. One of the two substrate supports 110 and 130 is moved in a first direction of movement B1 into the central overlapping area 600 so that transport belts located on substrate supports mesh with the transport belts of loading device 210. The circuit board L can then be transferred to substrate supports 110 or 130.

If circuit board L is to be transferred to one of the two substrate supports 120 or 140 or the second substrate support pair located after the first substrate supports 110 or 130, that is to circuit board position 2 or 4, about half of the loading device 210 is moved in load direction R1 into the central overlapping area 600. One of the two substrate supports 120 and 140 of the second pair of substrate supports is also moved into the central overlapping area 600, i.e. in a second direction of movement B2. The transport belts of substrate supports 120 or 140 and load device 210 must mesh with each other so circuit board L of load device 210 can be transferred to substrate supports 120 or 140 of the second pair of substrate supports. Subsequently substrate supports 120 or 140 are moved into the first assembly field 500 or the second assembly field 550 in the second direction of movement B2.

Circuit boards L which are located on one of the substrate supports in the first assembly field 500 or in the second assembly field 550 are assembled by means of a handling device as well as by feed modules from which components are fed to the handling device. Before assembly there is calibration of the circuit boards L which are located on one of the substrate supports 110, 130, 120 and 140. To this end the measurement system 300 is moved along the guide device 214 within the central overlapping area 600 over that substrate support which is carrying circuit board L. The substrate support is then positioned for transferring circuit board L from the loading device 210 into the central overlapping area 600. If the substrate support moves from the central overlapping area 600 into the first assembly field 500 or the second assembly field 550 along the first direction of movement B1 or the second direction of movement B2 all the required reference points for determining the position of circuit board L on substrate supports 110, 130, 120 or 140 as well as circuit board L pass through the field of view of measurement system 300. It is thus possible to determine the position of circuit board L on the substrate support without requiring additional processing time for this since the position can be determined during movement of the corresponding substrate support into the first assembly field 500 or the second assembly field 550.

It is possible to assemble components simultaneously in both assembly fields 500 and 550.

The feed devices are located in the area of assembly field 500 or 550 from which the components are fed to the handling devices. To be able to provide the largest possible variety of different components it can be necessary to move a circuit board to be assembled from one assembly field to another assembly field to enable the possible number of different components to be fully exploited.

For this purpose for example a circuit board located on substrate support 110 in circuit board position 1 can be moved from substrate support 110 into the central overlapping area 600. The circuit board is to be taken for example to substrate support 140 and to circuit board position 4. Substrate support 140 is thus also moved along the second direction of movement B2 into the central overlapping area in such a way that the transport belts of the two substrate supports 110 and 140 mesh with each other. Then circuit board L is transferred from substrate support 110 to substrate support 140. Subsequently substrate support 140 is moved into the second assembly field 550 where circuit board L can be assembled with further components in circuit board position 4.

It is also possible to basically transfer circuit boards along one direction of movement B1 or B2. To do this, the substrate support of a support pair bearing the corresponding circuit board is moved into the central movement area 600. Circuit board L is then transferred to the loading device 210 or to the unloading device 220, depending on which of the two is adjacent to the substrate support in the central overlapping area. Subsequently the other substrate support of the pair of substrate supports moves along the guide device 114 or 124 in the given direction of movement B1 or B2 into the central overlapping area 600 and takes the circuit board L from loading device 210 or from unloading device 220. Afterwards circuit board L can be brought on this substrate support into the other assembly field.

The assembly system eliminates the non-productive time for determining the position of the circuit board L on a substrate support 110, 130, 120 or 140 as well as the non-productive time for changing a substrate to be assembled in the assembly field. Since two pairs of substrate supports are provided, one substrate support can always be equipped with a circuit board L and be undergoing assembly while the other substrate support assigned to this assembly field can be moving a finished circuit board L for further transport into the central overlapping area 600 where it can be taken off the substrate support by means of the unloading device 220 and subsequently output at the output station 320. Simultaneously this substrate support can be equipped via the loading device 210 with a new circuit board L to be assembled which is then in its turn moved into the assembly field.

Furthermore it is also possible, while assembly is taking place for example in the two assembly fields 500 and 550 or no new circuit board L is required, to move a circuit board L along the conveyor run past the two assembly fields 500 and 550 to output station 320. To do this a circuit board L is transferred to loading device 210. Loading device 210 is moved in loading direction R1 into the central overlapping area. Likewise unloading device 220 is moved in the unloading direction R2 into the central overlapping area 600, so that the loading device and the unloading device adjoin each other.

Circuit board L is transferred from loading device 210 to unloading device 220. Unloading device 220 is moved into its rest position and from there can transfer the circuit board L to the output station 320. This makes it possible for example for circuit boards L to pass in direction of transport T when assembly is taking place in both assembly fields 500 and 550 for example or while a fault has arisen in the assembly field or in both assembly fields. The only requirement is that none of the substrate supports 110, 130, 120 or 140 are located in the central overlapping area 600.

It is also possible to position very large circuit boards L on two substrate supports at the same time. For this purpose the two substrate supports which are assigned to one of the assembly fields 500 or 550, i.e. substrate support 110 and 120 or substrate support 130 and 140, are mechanically coupled. Subsequently the coupled substrate supports 110, 120 or 130, 140 are moved into the central overlapping area. There the loading device 210 transfers to them an oversize circuit board which extends across the two substrate supports 110, 120 or 130, 140. Subsequently the oversize circuit board is moved from the mechanically coupled substrate supports 110, 120 or 130, 140 into the first assembly field 500 or the second assembly field 550. The oversize circuit board can be assembled there and subsequently moved in a similar way by means of the coupled substrate supports back into the central movement area 600 and output by the unloading device 220 and output station 320.

It is further possible guide devices 114 and 124 of the substrate support pairs to be deigned to long enough so that within an assembly field 550 or 500 in a direction of movement B1 and/or B2 both substrate supports 110, 130, or 120, 140 of the pairs of substrate supports are located along the guide device 114 or 124 and can thus be assembled. This can for example be useful to provide greater options for variation as regards the variety of components which are to be assembled on a circuit board L. In this case a circuit board L can be moved along one of the directions of movement B1 and B2 or from one of the assembly fields 500 or 550 into the other assembly field 550 or 500 with a circuit board that is already present there having to be removed beforehand.

1. Assembly system for assembling components on substrates, with the substrates (L) able to be fed in on an essentially linear conveyor run along which the substrates are essentially moved in one direction of transport (T), and whereby to both sides of the conveyor run at least one feed device for feeding in the components as well as at least one assembly field (500, 550) with a handling device for assembling the fed components on the substrates is located,
characterized in that
at least one pair of substrate supports is provided featuring two substrate supports (110, 130, 120, 140) of which one substrate support (110, 120, 130, 140) in each case is assigned to the assembly fields (500, 550) on one of the two sides along the conveyor run and can be moved in each case between the conveyor run and the assembly field (500, 550) assigned to it in an area of movement in a direction of movement (B1, B2) of the pair of substrate supports and
the assembly fields (500, 550) of a pair of substrate supports are arranged at intervals in relation to the conveyor run in the direction of movement (B1, B2) of the pair of substrate supports:

2. Assembly system according to claim 1,
characterized in that
the areas of movement of the substrate supports (110, 130, 120, 140) of each pair of substrate supports overlap in the area of the conveyor run.

3. Assembly system according to claim 1 or 2,
characterized in that
a first pair of substrate supports and a second pair of substrate supports are arranged one behind the other in the direction of transport (T).

4. Assembly system according to claim 1 to 3,
characterized in that
a loading device (210) is provided which, to load the substrate supports (110, 130, 120, 140) with substrates (L), can be moved along the conveyor run and for which the rest position lies in the direction of transport (T) before the pairs of substrate supports.

5. Assembly system according to claim 1 to 4,
characterized in that
an unloading device (220) is provided, which, to unload the substrates (L) from the substrate supports (110, 130, 120, 140) can be moved along the conveyor run and for which the rest position lies in the direction of transport (T) after the pairs of substrate supports.

6. Assembly system according to claim 4 or 5, characterized in that the loading device (210) or the unloading device (220) is supported over the conveyor run.

7. Assembly system according to one of the previous claims,
characterized in that,
a measurement system (300) to determine the position of the substrates (L) relative to reference points on the substrate supports (110, 130, 120, 140) is provided and
the measurement system (300) can be moved along the conveyor run above the substrate supports (110, 130, 120, 140).

8. Assembly system according to claim 7, characterized in that the measurement system (300) is supported above the conveyor run.

9. Assembly system according to claim 7 or 8,
characterized in that
the measurement system (300) features a camera and an evaluation unit.

10. Assembly system according to one of the previous claims,
characterized in that,
a transport device is located along the conveyor run, from which the substrates (L) can be transported in the direction of transport (T) to the loading device (210) or to the substrate supports (110, 130, 120, 140) and from which the substrates (L) can be transported away in the direction of transport (T) from the unloading device (220) or from the substrate supports (110, 130, 120, 140).

11. Assembly system according to claim 10,
characterized in that
the transport device features transport belts.

12. Assembly system according to one of the previous claims,
characterized in that
a second conveyor run is provided which is runs in parallel to the conveyor run and is located directly next to the conveyor run,
a second loading device similar to loading device (210) and a second unloading device similar to unloading device (220) are provided along the second conveyor run,
The substrates (L) can be transported in the direction of transport (T) to and from the substrate supports (110, 130, 120, 140) on one of the two sides of the conveyor run from the second loading device (210) and second unloading device (220), and
The substrates (L) can be transported in the direction of transport (T) to and from the substrate supports to the other of the two sides of the conveyor run from the loading device (210) and unloading device (220).

13. Assembly system according to one of the previous claims,
characterized in that
substrates (L) can be moved from a first assembly field (500) by means of the substrate supports (110, 130, 120, 140) or by means of the substrate supports (110, 130, 120, 140) and loading devices or by means of the substrate supports and unloading devices via the conveyor run to a second assembly field (550).

14. Assembly system according to claim 13,
characterized in that
the first assembly field (500) and the second assembly field (550) are arranged diagonally to one another in respect of the conveyor run.

15. Assembly plant with plurality of assembly systems according to one of claims 4 to 14,
characterized in that
the assembly systems are arranged in such as way that the area of movement of the loading device (210) of assembly system positioned downstream in the direction of transport (T) is directly adjacent to the area of movement of the substrate supports (110, 130, 120, 140) of the assembly system positioned upstream in the direction of transport (T).

16. Assembly plant with plurality of assembly systems according to one of claims 4 to 14,
characterized in that
the assembly systems are arranged in such as way that the area of movement of the loading device (210) of assembly system positioned downstream in the direction of transport (T) is directly adjacent to the area of movement of the substrate supports (220, 130, 120, 140) of the assembly system positioned upstream in the direction of transport (T).

17. Method for assembling components on substrates (L), with the substrates (L) being able to be fed in on an essentially linear conveyor run, along which the substrates (L) are essentially moved in a direction of transport (T) and whereby to both sides of the conveyor run at least one feed device for feeding components as well as at least one assembly field (500, 550) with a handling device for assembling the fed components on the substrates (L) is located,
characterized in that
the substrates (L) are moved by means of at least one pair of substrate supports featuring two substrate supports (110, 130, 120,140) from the conveyor run out into an area of movement (B1, B2) of the substrate supports (110, 130, 120,140) to the assembly fields (500, 550) on both sides of the conveyor run, with the area of movement overlapping with the conveyor run,
the substrates (L) are assembled at the assembly fields (500, 550) on the substrate supports (110, 130, 120,140) by means of handling devices.

18. Method according to claim 17, with a loading device (210) being provided to load the substrate supports (110, 130, 120,140) with substrates (L) which can be moved along the conveyor run and for which the rest position lies in the direction of transport (T) before the substrate supports (110, 130, 120,140),
characterized in that
for passing on the substrates (L) the loading device (210) is moved directly from an acceptance position to a transfer position,
the acceptance position is located in the direction of transport (T) before the substrate supports (110, 130, 120,140) and before the rest position of the loading device (210),
the transfer position is located in the direction of transport (T) after the substrate supports (110, 130, 120,140).

19. Method according to claim 18, with an unloading device (220) for removing the substrates (L) from the substrate supports (110, 130, 120,140) being provided which can be moved along the conveyor run and for which the rest position lies in the direction of transport (T) after the substrate supports (110, 130, 120,140),
characterized in that
for passing on the substrates (L) the loading device (210) is moved directly from the acceptance position to an intermediate position,
the unloading device (220) is moved directly from the intermediate position into the transfer position and
the intermediate position lies in the direction of transport (T) in the area of the substrate support (110, 130, 120,140).

20. Method according to one of the previous claims, with a measurement system (300) being provided for determining the position of the substrates (L) relative to reference points on the substrate supports (110, 130, 120,140) which can be moved along the conveyor run over the substrate supports ( 110, 130, 120,140),
characterized in that
The position of the substrates (L) is determined by the measurement system (300) while the substrate supports (110, 130, 120,140) are being moved to the assembly fields (500, 550).

21. Method according to one of the previous claims, with at least two pairs of substrate supports being arranged one after the other in the direction of transport (T), characterized in that
substrates (L) are moved in each case by at least two substrate supports (110, 130, 120,140) on each side of the conveyor run to an a assembly field (550, 550) on this side,
the substrate supports (110, 130, 120,140) are moved alternately in each case between the assembly field (500, 550) and the conveyor run,
while a substrate (L) which is located on a substrate support (110, 130, 120,140) is being assembled by the handling device in the assembly field (500, 550) on another substrate support (110, 130, 120,140) another substrate (L) located in the area of the conveyor run, is being taken off and/or moved between the assembly field (500, 550) and the conveyor run.
